(19) United States
(12) Patent Application Publication
(10) Pub. No.: US 2022/0187708 A1
(43) Pub. Date: Jun. 16, 2022

(54) POLYMER AND POSITIVE RESIST COMPOSITION

(71) Applicant: ZEON CORPORATION, Chiyoda-ku, Tokyo (JP)

(72) Inventor: Manabu HOSHINO, Chiyoda-ku, Tokyo (JP)

(73) Assignee: ZEON CORPORATION, Chiyoda-ku, Tokyo (JP)

(21) Appl. No.: 17/594,461

(22) PCT Filed: Apr. 13, 2020
(86) PCT No.: PCT/JP2020/016338

§ 371 Date: Oct. 18, 2021

(30) Foreign Application Priority Data
Apr. 26, 2019 (JP) 2019-086703
Oct. 25, 2019 (JP) 2019-194652

(51) Int. Cl. G03F 7/039; G03F 7/20; G03F 7/32

(52) U.S. Cl. CPC G03F 7/0392; G03F 7/325; G03F 7/2004

(57) ABSTRACT

Provided is a polymer capable of forming a resist pattern in which pattern top loss is inhibited when used as a main chain scission-type positive resist. The polymer includes a monomer unit (A) represented by general formula (I), shown below, and a monomer unit (B) represented by general formula (II), shown below, and the proportion of components having a molecular weight of 100,000 or more in the polymer is 10% or more. In general formula (I), X is a fluorine, chlorine, bromine, iodine, or astatine atom, and R¹ is an organic group including 3 to 7 fluorine atoms. In general formula (II), R² is a hydrogen atom, fluorine atom, unsubstituted alkyl group, or fluorine atom-substituted alkyl group, R³ is a hydrogen atom, unsubstituted alkyl group, or fluorine atom-substituted alkyl group, p and q are integers of 0 to 5, and p+q=5.

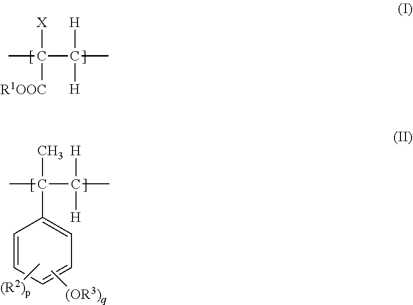

### TECHNICAL FIELD

The present disclosure relates to a polymer and a positive resist composition.

### BACKGROUND

Polymers that undergo main chain scission to lower molecular weight upon irradiation with ionizing radiation such as an electron beam or short-wavelength light such as ultraviolet light (inclusive of extreme ultraviolet (EUV)) are conventionally used as main chain scission-type positive resists in fields such as semiconductor production. (Hereinafter, the term “ionizing radiation or the like” is used to refer collectively to ionizing radiation and short-wavelength light.)

Such a polymer is used in the form of a positive resist composition that contains the polymer and a solvent, for example, in order to form a resist pattern. Specifically, the positive resist composition is supplied onto a substrate, and then the solvent is removed therefrom to form a resist film that is subsequently irradiated with ionizing radiation or the like (i.e., exposed) so as to write a desired pattern. Next, the exposed resist film is brought into contact with a developer (i.e., developed) so as to dissolve an exposed section of the resist film and form a resist pattern that is formed of an unexposed section on the substrate.

Attempts are being made to improve polymers that can be used as main chain scission-type positive resists in order to improve characteristics of resist patterns.

As one example, a specific polymer including an α-chloroacrylic acid fluoro ester unit that includes an organic group including not fewer than 5 and not more than 7 fluorine atoms has been proposed in Patent Literature (PTL) 1 as a polymer that can be used as a main chain scission-type positive resist.

According to PTL 1, this polymer has excellent sensitivity when used as a positive resist, and, by using a positive resist composition that contains this polymer to form a resist pattern, it is possible to ensure clarity of the obtained resist pattern while also inhibiting collapse of the resist pattern.

### CITATION LIST

### Patent Literature

PTL 1: WO2018/123667A1

### SUMMARY

### Technical Problem

However, studies conducted by the inventor have revealed that when a resist film formed from the conventional positive resist composition described above is exposed and developed, there are cases in which not only an exposed section, but also part of an unexposed section undergoes unintended dissolution, and in which film reduction of a top section of a resist pattern occurs (i.e., pattern top loss occurs).

Put another way, there is room for further improvement of the conventional technique described above in terms of inhibiting pattern top loss of an obtained resist pattern.

Accordingly, one object of the present disclosure is to provide a polymer that can be used well as a positive resist capable of forming a resist pattern in which pattern top loss is inhibited.

Another object of the present disclosure is to provide a positive resist composition that is capable of forming a resist pattern in which pattern top loss is inhibited.

### Solution to Problem

The inventor conducted diligent investigation with the aim of solving the problem set forth above. The inventor discovered that a positive resist composition that enables good formation of a resist pattern in which pattern top loss is inhibited can be produced by using a polymer that is formed using specific monomers and in which the proportion of components having a molecular weight of 100,000 or more is not less than a specific value, and, in this manner, completed the present disclosure.

Specifically, the present disclosure aims to advantageously solve the problem set forth above, and a presently disclosed polymer comprises: a monomer unit (A) represented by general formula (I), shown below,

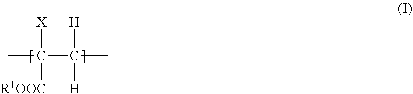

where, in general formula (I), X is a fluorine atom, a chlorine atom, a bromine atom, an iodine atom, or an astatine atom, and R¹ is an organic group including not fewer than 3 and not more than 7 fluorine atoms; and

a monomer unit (B) represented by general formula (II), shown below,

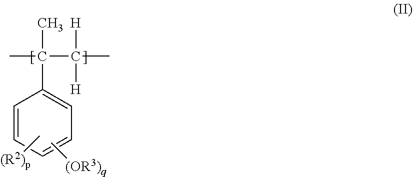

where, in general formula (II), R² is a hydrogen atom, a fluorine atom, an unsubstituted alkyl group, or a fluorine atom-substituted alkyl group, R³ is a hydrogen atom, an unsubstituted alkyl group, or a fluorine atom-substituted alkyl group, p and q are integers of not less than 0 and not more than 5, and p+q=5, wherein a proportion of components having a molecular weight of 100,000 or more is 10% or more. When a polymer that includes the monomer unit (A) and the monomer unit (B) and in which the proportion of components having a molecular weight of 100,000 or more is not less than the value set forth above in this manner is used as a positive resist, it is possible to form a resist pattern in which pattern top loss is inhibited.

Note that the “proportion of components having a molecular weight of 100,000 or more” referred to in the present disclosure can be determined using a chromatogram obtained by gel permeation chromatography by calculating a proportion of the total area (C) of peaks for components having a molecular weight of 100,000 or more in the chromatogram relative to the total area (A) of all peaks in the chromatogram (=(C/A)×100%).

Also note that in a case in which p in general formula (II) is 2 or more, each R² may be the same or different, and in a case in which q in general formula (II) is 2 or more, each R³ may be the same or different.

In the presently disclosed polymer, X in general formula (I) is preferably a chlorine atom. When X in general formula (I) is a chlorine atom, main chain scission properties of the polymer upon irradiation with ionizing radiation or the like can be improved, and pattern top loss of a resist pattern can be further inhibited. Moreover, the polymer is easier to produce.

In the presently disclosed polymer, a proportion of components having a molecular weight of less than 10,000 is preferably 0.5% or less. When the proportion of components having a molecular weight of less than 10,000 in the polymer is not more than the value set forth above, resolution of an obtained resist pattern can be improved, and pattern top loss can be further inhibited.

Note that the “proportion of components having a molecular weight of less than 10,000” referred to in the present disclosure can be determined using a chromatogram obtained by gel permeation chromatography by calculating a proportion of the total area (B) of peaks for components having a molecular weight of 10,000 or less in the chromatogram relative to the total area (A) of all peaks in the chromatogram (=(B/A)×100%).

The presently disclosed polymer preferably has a weight-average molecular weight (Mw) of more than 60,000. When the weight-average molecular weight (Mw) of the polymer is more than the value set forth above, pattern top loss of an obtained resist pattern can be further inhibited.

Note that the “weight-average molecular weight” referred to in the present disclosure can be measured as a standard polystyrene-equivalent value by gel permeation chromatography.

The presently disclosed polymer preferably has a molecular weight distribution (Mw/Mn) of less than 2.3. When the molecular weight distribution (Mw/Mn) of the polymer is less than the value set forth above, pattern top loss of an obtained resist pattern can be further inhibited.

Note that the “molecular weight distribution” referred to in the present disclosure can be determined by calculating a ratio of weight-average molecular weight relative to number-average molecular weight (weight-average molecular weight/number-average molecular weight). Also note that the “number-average molecular weight” and “weight-average molecular weight” referred to in the present disclosure can be measured as standard polystyrene-equivalent values by gel permeation chromatography.

Moreover, the present disclosure aims to advantageously solve the problem set forth above, and a presently disclosed positive resist composition comprises: any one of the polymers set forth above; and a solvent. Through a positive resist composition that contains the polymer set forth above in this manner, it is possible to form a resist pattern in which pattern top loss is inhibited. cl Advantageous Effect

According to the present disclosure, it is possible to provide a polymer that can be used well as a positive resist capable of forming a resist pattern in which pattern top loss is inhibited.

Moreover, according to the present disclosure, it is possible to provide a positive resist composition that is capable of forming a resist pattern in which pattern top loss is inhibited.

### DETAILED DESCRIPTION

The following provides a detailed description of embodiments of the present disclosure.

The presently disclosed polymer can be used well as a main chain scission-type positive resist that undergoes main chain scission to lower molecular weight upon irradiation with ionizing radiation, such as an electron beam, or short-wavelength light, such as ultraviolet light (inclusive of EUV). The presently disclosed positive resist composition contains the presently disclosed polymer as a positive resist and can suitably be used, for example, in formation of a resist pattern in a production process of a printed board such as a build-up board, a semiconductor, a photomask, a mold, or the like.

(Polymer)

The presently disclosed polymer includes: a monomer unit (A) represented by general formula (I), shown below,

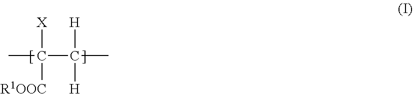

where, in general formula (I), X is a fluorine atom, a chlorine atom, a bromine atom, an iodine atom, or an astatine atom, and R¹ is an organic group including not fewer than 3 and not more than 7 fluorine atoms; and

a monomer unit (B) represented by general formula (II), shown below,

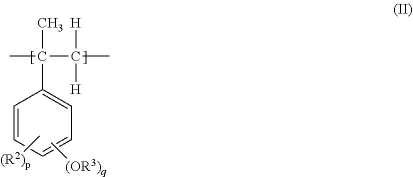

where, in general formula (II), R² is a hydrogen atom, a fluorine atom, an unsubstituted alkyl group, or a fluorine atom-substituted alkyl group, R³ is a hydrogen atom, an unsubstituted alkyl group, or a fluorine atom-substituted alkyl group, p and q are integers of not less than 0 and not more than 5, and p+q=5, wherein a proportion of components having a molecular weight of 100,000 or more is 10% or more.

Note that although the presently disclosed polymer may also include any monomer units other than the monomer unit (A) and the monomer unit (B), the proportion constituted by the monomer unit (A) and the monomer unit (B) among all monomer units of the polymer is, in total, preferably 90 mol % or more, more preferably substantially 100 mol %, and even more preferably 100 mol % (i.e., the polymer even more preferably only includes the monomer unit (A) and the monomer unit (B)).

The presently disclosed polymer may be a random polymer, a block polymer, an alternating polymer (ABAB . . . ), or the like, for example, so long as it includes the monomer unit (A) and the monomer unit (B), but is preferably a polymer that comprises 90 mass % or more (upper limit 100 mass %) of an alternating polymer. Moreover, it is preferable that alternating polymer molecules do not form a cross-linked product. The presently disclosed polymer has a low tendency to form a cross-linked product as a result of R¹ of the monomer unit (A) including fluorine atoms.

As a result of including the specific monomer unit (A) and the specific monomer unit (B), the presently disclosed polymer undergoes main chain scission to lower molecular weight upon being irradiated with ionizing radiation or the like (for example, an electron beam, a KrF laser, an ArF laser, an EUV laser, or the like). Furthermore, as a result of the presently disclosed polymer including the specific monomer unit (A) and the specific monomer unit (B) and the proportion of components having a molecular weight of 100,000 or more being not less than the value set forth above, the polymer enables formation of a resist pattern in which pattern top loss is inhibited. Although it is not clear why pattern top loss of a resist pattern can be reduced by using the presently disclosed polymer as a positive resist as compared to when a conventional polymer is used, the reason for this is presumed to be as follows.

When a resist pattern is formed using a resist composition containing a conventional polymer, there are cases in which unintended dissolution of resist film in an unexposed section occurs during development and in which film reduction of a top section of the resist pattern occurs as previously described. Such dissolution of an unexposed section is thought to be due to ionizing radiation or the like being reflected by a substrate during exposure, for example, and thereby causing main chain scission of polymer in the unexposed section. In response to this problem, the presently disclosed polymer contains components having a molecular weight of 100,000 or more in a proportion of 10% or more. In the case of the presently disclosed polymer containing high molecular weight components having a molecular weight of 100,000 or more in a high proportion of 10% or more, even when main chain scission of polymer in an unexposed section occurs, the molecular weight of the polymer in the unexposed section is not excessively reduced. In addition, as a result of low molecular weight components in the polymer being present in an entwined state with high molecular weight components having a molecular weight of 100,000 or more, dissolution of these low molecular weight components in a developer during a development step performed after exposure is inhibited. Therefore, it is thought that the inclusion of components having a molecular weight of 100,000 or more in a proportion of 10% or more in the polymer can inhibit a phenomenon in which part of a resist film in an unexposed section dissolves in a developer and can reduce the extent of loss of a top section of a resist pattern.

Accordingly, it is possible to form a resist pattern in which pattern top loss is inhibited by using the presently disclosed polymer.

<Monomer Unit (A)>

The monomer unit (A) is a structural unit that is derived from a monomer (a) represented by general formula (III), shown below.

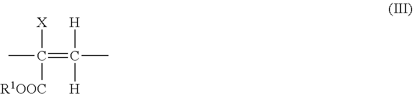

(In general formula (III), X and 10 are the same as in general formula (I).)

The proportion constituted by the monomer unit (A) among all monomer units of the polymer is not specifically limited but can be set as not less than 30 mol % and not more than 70 mol %, for example, and is preferably not less than 40 mol % and not more than 60 mol %, and more preferably not less than 45 mol % and not more than 55 mol %.

X in general formula (I) and general formula (III) is required to be a fluorine atom, a chlorine atom, a bromine atom, an iodine atom, or an astatine atom from a viewpoint of efficiency of absorption of ionizing radiation or the like. Moreover, X in general formula (I) and general formula (III) is preferably a chlorine atom from a viewpoint of improving main chain scission properties of the polymer upon irradiation with ionizing radiation or the like and inhibiting pattern top loss of a resist pattern. Also note that a monomer (a) for which X in general formula (III) is a chlorine atom is superior in terms of having excellent polymerizability, whereas a presently disclosed polymer including a monomer unit (A) for which X in general formula (I) is a chlorine atom is superior in terms of being easy to produce.

R¹ in general formula (I) and general formula (III) is required to be an organic group including not fewer than 3 and not more than 7 fluorine atoms. When the number of fluorine atoms in R¹ is 2 or less, the polymer cannot be provided with adequate main chain scission properties upon irradiation with ionizing radiation or the like. On the other hand, when the number of fluorine atoms in R¹ is 8 or more, pattern top loss of a resist pattern cannot be sufficiently inhibited. Moreover, clarity of a resist pattern cannot be improved. R¹ in general formula (I) and general formula (III) is preferably an organic group including not fewer than 3 and not more than 5 fluorine atoms, and more preferably an organic group including 5 fluorine atoms.

The number of carbon atoms in 10 is preferably not less than 2 and not more than 10, more preferably not less than 3 and not more than 4, and even more preferably 3. Sufficient solubility of the polymer in a developer after exposure can be ensured when the number of carbon atoms in R¹ is 2 or more, whereas excessive glass-transition temperature lowering does not occur, sufficient clarity of an obtained resist pattern can be ensured, and pattern top loss can be further inhibited when the number of carbon atoms in R¹ is 10 or less.

More specifically, R¹ in general formula (I) and general formula (III) is preferably a fluoroalkyl group including not fewer than 3 and not more than 7 fluorine atoms, a fluoroalkoxyalkyl group including not fewer than 3 and not more than 7 fluorine atoms, or a fluoroalkoxyalkenyl group including not fewer than 3 and not more than 7 fluorine atoms, and is more preferably a fluoroalkyl group including not fewer than 3 and not more than 7 fluorine atoms.

The fluoroalkyl group including not fewer than 3 and not more than 7 fluorine atoms may be a 2,2,2-trifluoroethyl group (number of fluorine atoms: 3; number of carbon atoms: 2), a 2,2,3,3,3-pentafluoropropyl group (number of fluorine atoms: 5; number of carbon atoms 3; structural formula (X), shown below), a 3,3,4,4,4-pentafluorobutyl group (number of fluorine atoms: 5; number of carbon atoms: 4; structural formula (Y), shown below), a 1H-1-(trifluoromethyl)trifluoroethyl group (number of fluorine atoms: 6; number of carbon atoms: 3), a 1H,1H,3H-hexafluorobutyl group (number of fluorine atoms: 6; number of carbon atoms: 4), a 2,2,3,3,4,4,4-heptafluorobutyl group (number of fluorine atoms: 7; number of carbon atoms: 4), or a 1,2,2,2-tetrafluoro-1-(trifluoromethyl)ethyl group (number of fluorine atoms: 7; number of carbon atoms: 3), for example. Of these examples, a 2,2,3,3,3-pentafluoropropyl group (number of fluorine atoms: 5; number of carbon atoms: 3; structural formula X, shown below) is preferable.

The fluoroalkoxyalkyl group including not fewer than 3 and not more than 7 fluorine atoms may be a pentafluoroethoxymethyl group (number of fluorine atoms: 5; number of carbon atoms: 3) or a pentafluoroethoxyethyl group (number of fluorine atoms: 5; number of carbon atoms: 4), for example.

The fluoroalkoxyalkenyl group including not fewer than 3 and not more than 7 fluorine atoms may be a pentafluoroethoxyvinyl group (number of fluorine atoms: 5; number of carbon atoms: 4), for example.

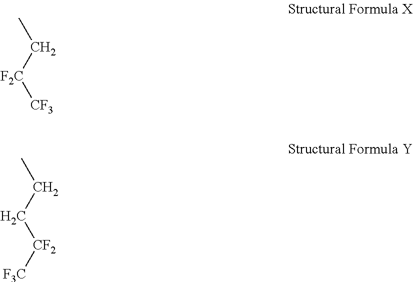

Examples of the monomer (a) represented by general formula (III) described above that can form the monomer unit (A) represented by general formula (I) described above include, but are not specifically limited to, α-chloroacrylic acid fluoroalkyl esters such as 2,2,2-trifluoroethyl α-chloroacrylate (number of fluorine atoms: 3), 2,2,3,3,3-pentafluoropropyl α-chloroacrylate (number of fluorine atoms: 5), 3,3,4,4,4-pentafluorobutyl α-chloroacrylate (number of fluorine atoms: 5), 1H-1-(trifluoromethyl)trifluoroethyl α-chloroacrylate (number of fluorine atoms: 6), 1H,1H,3H-hexafluorobutyl α-chloroacrylate (number of fluorine atoms: 6), 1,2,2,2-tetrafluoro-1-(trifluoromethyl)ethyl α-chloroacrylate (number of fluorine atoms: 7), and 2,2,3,3,4,4,4-heptafluorobutyl α-chloroacrylate (number of fluorine atoms: 7); α-chloroacrylic acid fluoroalkoxyalkyl esters such as pentafluoroethoxymethyl α-chloroacrylate (number of fluorine atoms:

5) and pentafluoroethoxyethyl α-chloroacrylate (number of fluorine atoms: 5); and α-chloroacrylic acid fluoroalkoxyalkenyl esters such as pentafluoroethoxyvinyl α-chloroacrylate (number of fluorine atoms: 5).

The monomer unit (A) is preferably a structural unit that is derived from an α-chloroacrylic acid fluoroalkyl ester. Moreover, the monomer unit (A) is more preferably a structural unit that, from among α-chloroacrylic acid fluoroalkyl esters, is derived from 2,2,3,3,3-pentafluoropropyl α-chloroacrylate. When the monomer unit (A) is a structural unit that is derived from 2,2,3,3,3-pentafluoropropyl α-chloroacrylate, pattern top loss of a resist pattern can be even further inhibited. Moreover, main chain scission properties of the polymer upon irradiation with ionizing radiation or the like can be sufficiently ensured while also increasing resolution of a resist pattern.

<Monomer Unit (B)>

The monomer unit (B) is a structural unit that is derived from a monomer (b) represented by general formula (IV), shown below.

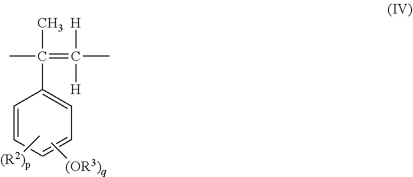

(In general formula (IV), R², R³, p, and q are the same as in general formula (II).)

The proportion constituted by the monomer unit (B) among all monomer units of the polymer is not specifically limited but can be set as not less than 30 mol % and not more than 70 mol %, for example, and is preferably not less than 40 mol % and not more than 60 mol %, and more preferably not less than 45 mol % and not more than 55 mol %.

Examples of fluorine atom-substituted alkyl groups that can constitute R² and R³ in general formula (II) and general formula (IV) include, but are not specifically limited to, groups having a structure in which some or all of the hydrogen atoms in an alkyl group are replaced with fluorine atoms.

Examples of unsubstituted alkyl groups that can constitute R² and R³ in general formula (II) and general formula (IV) include, but are not specifically limited to, unsubstituted alkyl groups including not fewer than 1 and not more than 5 carbon atoms. Of such alkyl groups, a methyl group or an ethyl group is preferable as an unsubstituted alkyl group that can constitute R² and R³.

From a viewpoint of improving ease of production of the polymer, every R² and/or R³ present in general formula (II) and general formula (IV) is preferably a hydrogen atom or an unsubstituted alkyl group, more preferably a hydrogen atom or an unsubstituted alkyl group including not fewer than 1 and not more than 5 carbon atoms, and even more preferably a hydrogen atom.

Also note that from a viewpoint of improving ease of production of the polymer, it is preferable that, in general formula (II) and general formula (IV), p is 5, q is 0, and each of the five R² groups is a hydrogen atom or an unsubstituted alkyl group, more preferable that each of the five R² groups is a hydrogen atom or an unsubstituted alkyl group including not fewer than 1 and not more than 5 carbon atoms, and even more preferable that each of the five R² groups is a hydrogen atom.

Examples of the monomer (b) represented by general formula (IV) described above that can form the monomer unit (B) represented by general formula (II) described above include, but are not specifically limited to, α-methylstyrene (AMS) and derivatives thereof (for example, 4-fluoro-α-methylstyrene (4FAMS) in accordance with general formula (b-2)) such as (b-1) to (b-11), shown below.

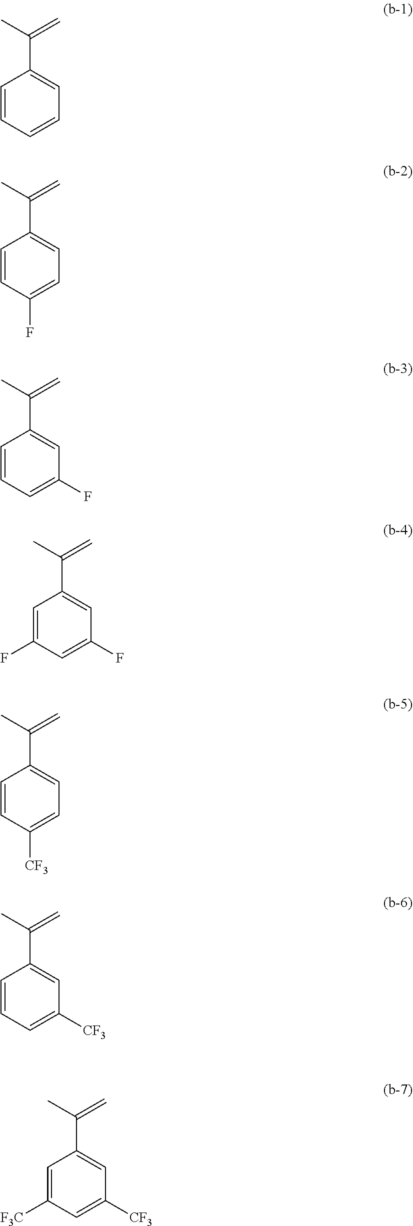

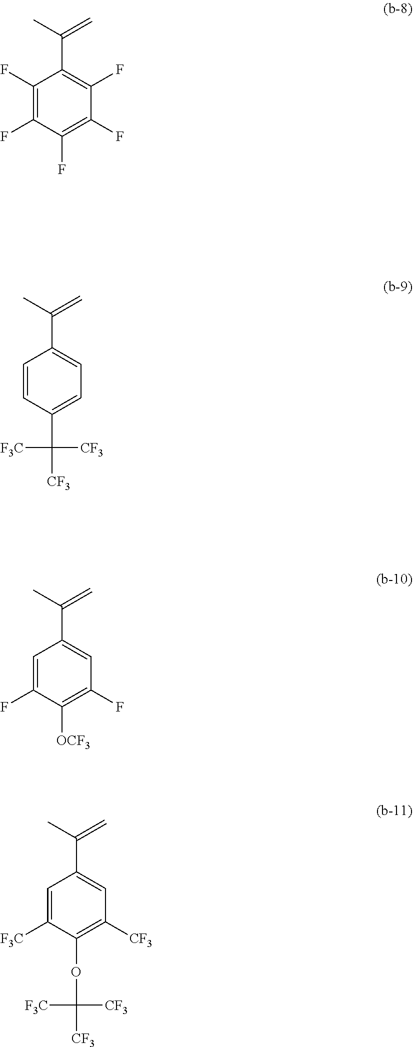

Note that from a viewpoint of improving ease of production of the polymer, it is preferable that the monomer unit (B) does not include a fluorine atom (i.e., that only the monomer unit (A) includes fluorine atoms), and more preferable that the monomer unit (B) is a structural unit derived from α-methylstyrene. In other words, it is particularly preferable for p, q, R², and R³ in general formula (II) and general formula (IV) that p=5, q=0, and each of the five R² groups is a hydrogen atom.

<Proportion of Components Having Molecular Weight of 100,000 or More>

The proportion of components having a molecular weight of 100,000 or more in the presently disclosed polymer is required to be 10% or more, and is preferably 13% or more, more preferably 16% or more, and even more preferably 18% or more. When the proportion of components having a molecular weight of 100,000 or more is less than 10%, pattern top loss of a resist pattern cannot be sufficiently inhibited. Moreover, resolution of a resist pattern decreases. Although no specific limitations are placed on the upper limit for the proportion of components having a molecular weight of 100,000 or more, the upper limit can be set as 95% or less, or as 85% or less, for example, from a viewpoint of improving producibility of the polymer.

<Proportion of Components Having Molecular Weight of Less than 10,000>

The proportion of components having a molecular weight of less than 10,000 in the presently disclosed polymer is preferably 0.5% or less, more preferably 0.4% or less, even more preferably 0.25% or less, further preferably 0.2% or less, and particularly preferably 0.15% or less. When the proportion of components having a molecular weight of less than 10,000 is 0.5% or less, resolution of a resist pattern can be improved, and pattern top loss can be further inhibited. Although no specific limitations are placed on the lower limit for the proportion of components having a molecular weight of less than 10,000, the lower limit can be set as 0.01% or more, or as 0.02% or more, for example.

<Proportion of components Having Molecular Weight of 120,000 or More>

The proportion of components having a molecular weight of 120,000 or more in the presently disclosed polymer is preferably 8% or more, more preferably 10% or more, even more preferably 12% or more, and particularly preferably 14% or more. When the proportion of components having a molecular weight of 120,000 or more is 8% or more, resolution of a resist pattern can be improved, and pattern top loss can be further inhibited. Although no specific limitations are placed on the upper limit for the proportion of components having a molecular weight of 120,000 or more, the upper limit can be set as 90% or less, or as 80% or less, for example, from a viewpoint of improving producibility of the polymer.

Note that the “proportion of components having a molecular weight of 120,000 or more” referred to in the present disclosure can be determined using a chromatogram obtained by gel permeation chromatography by calculating a proportion of the total area (D) of peaks for components having a molecular weight of 120,000 or more in the chromatogram relative to the total area (A) of all peaks in the chromatogram (=(D/A)×100%).

<Proportion of Components Having Molecular Weight of 140,000 or More>

The proportion of components having a molecular weight of 140,000 or more in the presently disclosed polymer is preferably 5% or more, more preferably 6% or more, even more preferably 7% or more, and particularly preferably 7.5% or more. When the proportion of components having a molecular weight of 140,000 or more is 5% or more, resolution of a resist pattern can be improved, and pattern top loss can be further inhibited. Although no specific limitations are placed on the upper limit for the proportion of components having a molecular weight of 140,000 or more, the upper limit can be set as 80% or less, or as 70% or less, for example, from a viewpoint of improving producibility of the polymer.

Note that the “proportion of components having a molecular weight of 140,000 or more” referred to in the present disclosure can be determined using a chromatogram obtained by gel permeation chromatography by calculating a proportion of the total area (E) of peaks for components having a molecular weight of 140,000 or more in the chromatogram relative to the total area (A) of all peaks in the chromatogram (=(E/A)×100%).

<Proportion of Components Having Molecular Weight of 200,000 or More>

The proportion of components having a molecular weight of 200,000 or more in the presently disclosed polymer is preferably 2% or more, more preferably 2.5% or more, even more preferably 2.7% or more, and particularly preferably 3% or more. When the proportion of components having a molecular weight of 200,000 or more is 2% or more, resolution of a resist pattern can be improved, and pattern top loss can be further inhibited. Although no specific limitations are placed on the upper limit for the proportion of components having a molecular weight of 200,000 or more, the upper limit can be set as 70% or less, or as 50% or less, for example, from a viewpoint of improving producibility of the polymer.

Note that the “proportion of components having a molecular weight of 200,000 or more” referred to in the present disclosure can be determined using a chromatogram obtained by gel permeation chromatography by calculating a proportion of the total area (F) of peaks for components having a molecular weight of 200,000 or more in the chromatogram relative to the total area (A) of all peaks in the chromatogram (=(F/A)×100%).

<Weight-average Molecular Weight>

The weight-average molecular weight (Mw) of the presently disclosed polymer is preferably more than 60,000, more preferably more than 100,000, even more preferably more than 110,000, further preferably more than 125,000, and particularly preferably more than 150,000, and is preferably less than 500,000, more preferably less than 300,000, even more preferably less than 250,000, and particularly preferably less than 200,000. When the weight-average molecular weight (Mw) of the polymer is more than 60,000, pattern top loss of a resist pattern can be further inhibited. On the other hand, when the weight-average molecular weight (Mw) of the polymer is less than 500,000, sensitivity in formation of a resist pattern can be improved. Moreover, producibility of the polymer can be ensured while also improving clarity of a resist pattern. Furthermore, when the weight-average molecular weight (Mw) of the polymer is less than 200,000, the aforementioned effects of ensuring producibility of the polymer and improving clarity of a resist pattern can be obtained extremely well.

<Number-average Molecular Weight>

The number-average molecular weight (Mn) of the presently disclosed polymer is preferably more than 36,000, more preferably more than 60,000, even more preferably more than 70,000, further preferably more than 80,000, and particularly preferably more than 90,000, and is preferably less than 300,000, more preferably less than 200,000, even more preferably less than 160,000, and particularly preferably less than 130,000. When the number-average molecular weight (Mn) of the polymer is more than 36,000, pattern top loss of a resist pattern can be further inhibited. On the other hand, when the number-average molecular weight (Mn) of the polymer is less than 300,000, sensitivity in formation of a resist pattern can be improved. Moreover, producibility of the polymer can be ensured while also improving clarity of a resist pattern. Furthermore, when the number-average molecular weight (Mn) of the polymer is less than 130,000, the aforementioned effects of ensuring producibility of the polymer and improving clarity of a resist pattern can be obtained extremely well.

<Molecular Weight Distribution>

The molecular weight distribution (Mw/Mn) of the presently disclosed polymer is preferably less than 2.3, more preferably less than 2.0, even more preferably less than 1.6, further preferably less than 1.5, and particularly preferably less than 1.48, and is preferably more than 1.3, more preferably more than 1.35, even more preferably more than 1.39, further preferably more than 1.4, and particularly preferably more than 1.41. When the molecular weight distribution (Mw/Mn) of the polymer is less than 2.3, pattern top loss of a resist pattern can be further inhibited. On the other hand, when the molecular weight distribution (Mw/Mn) of the polymer is more than 1.3, the polymer is easier to produce.

<Production Method of Polymer>

The polymer including the monomer unit (A) and the monomer unit (B) set forth above can be produced, for example, by carrying out polymerization of a monomer composition that contains the monomer (a) and the monomer (b), and then optionally purifying the obtained polymerized product.

The chemical composition, molecular weight distribution, weight-average molecular weight, and number-average molecular weight of the polymer, and the proportions of components having various molecular weights in the polymer can be adjusted by altering the polymerization conditions and the purification conditions. Specifically, the chemical composition of the polymer can be adjusted by altering the proportional content of each monomer in the monomer composition used in polymerization, for example. Moreover, the proportion of high molecular weight components (for example, components having a molecular weight of 100,000 or more), the weight-average molecular weight, and the number-average molecular weight can be increased by lowering the polymerization temperature. Furthermore, the proportion of high molecular weight components (for example, components having a molecular weight of 100,000 or more), the weight-average molecular weight, and the number-average molecular weight can be increased by lengthening the polymerization time. It is preferable to lower the polymerization temperature and lengthen the polymerization time in production of the presently disclosed polymer from a viewpoint of increasing the proportion of high molecular weight components (for example, components having a molecular weight of 100,000 or more) in the obtained polymer and also increasing the weight-average molecular weight and the number-average molecular weight of the polymer.

[Polymerization of Monomer Composition]

The monomer composition used in production of the polymer may be a mixture of monomer components that include the monomer (a) and the monomer (b), an optionally useable solvent, an optionally useable polymerization initiator, and optionally added additives. Polymerization of the monomer composition may be carried out by a known method. In particular, in a case in which a solvent is used, it is preferable that cyclopentanone or the like is used as the solvent. Moreover, it is preferable that a radical polymerization initiator such as azobisisobutyronitrile is used as the polymerization initiator. Note that the proportion of high molecular weight components (for example, components having a molecular weight of 100,000 or more) and the weight-average molecular weight and number-average molecular weight of the polymer can be increased by reducing the amount of the polymerization initiator that is used, and, conversely, can be reduced by increasing the amount of the polymerization initiator that is used. It is preferable to reduce the amount of the polymerization initiator that is used in production of the presently disclosed polymer from a viewpoint of increasing the proportion of high molecular weight components (for example, components having a molecular weight of 100,000 or more) in the obtained polymer and also increasing the weight-average molecular weight and the number-average molecular weight of the polymer.

A polymerized product obtained through polymerization of the monomer composition may be used as the polymer as obtained or may, without any specific limitations, be collected by adding a good solvent such as tetrahydrofuran to a solution containing the polymerized product and subsequently dripping the solution to which the good solvent has been added into a poor solvent such as methanol to coagulate the polymerized product, and then the polymerized product may be purified as described below.

[Purification of Polymerized Product]

The purification method used to purify the resultant polymerized product to obtain the polymer having the properties set forth above may be, but is not specifically limited to, a known purification method such as reprecipitation or column chromatography. Of these purification methods, purification by reprecipitation is preferable.

Also note that purification of the polymerized product may be repeated multiple times.

Purification of the polymerized product by reprecipitation is, for example, preferably carried out by dissolving the resultant polymerized product in a good solvent such as tetrahydrofuran, and subsequently dripping the resultant solution into a mixed solvent of a good solvent, such as tetrahydrofuran, and a poor solvent, such as methanol, to cause precipitation of a portion of the polymerized product. When purification of the polymerized product is carried out by dripping a solution of the polymerized product into a mixed solvent of a good solvent and a poor solvent as described above, the molecular weight distribution, weight-average molecular weight, number-average molecular weight, and proportion of high molecular weight components (for example, components having a molecular weight of 100,000 or more) in the resultant polymer can easily be adjusted by altering the types and/or mixing ratio of the good solvent and the poor solvent. In one specific example, the molecular weight of polymer that precipitates in the mixed solvent can be increased by increasing the proportion of the good solvent in the mixed solvent.

Also note that in a situation in which the polymerized product is purified by re-precipitation, polymer that precipitates in the mixed solvent of the good solvent and the poor solvent may be used as the presently disclosed polymer, or polymer that does not precipitate in the mixed solvent (i.e., polymer dissolved in the mixed solvent) may be used as the presently disclosed polymer, so long as the polymer that is used has the desired properties. Polymer that does not precipitate in the mixed solvent can be collected from the mixed solvent by a known technique such as concentration to dryness.

### Example of Production Method of Polymer

The following provides a detailed description of conditions in one example of a method of producing the presently disclosed polymer. However, the conditions in production of the presently disclosed polymer are not limited to the conditions set forth below.

In one example of a method of producing the polymer, it is preferable that polymerization is performed for a long time while also setting a comparatively low polymerization temperature. The use of such a production method enables good production of the presently disclosed polymer in which the proportion of components having a molecular weight of 100,000 or more is 10% or more.

Specifically, the polymerization temperature is preferably −5° C. or higher, more preferably 20° C. or higher, even more preferably 40° C. or higher, and particularly preferably 50° C. or higher, and is preferably 65° C. or lower, more preferably 60° C. or lower, and even more preferably 55° C. or lower.

Adopting a polymerization temperature of −5° C. or higher makes it easy to set the polymerization temperature. On the other hand, adopting a polymerization temperature of 65° C. or lower makes it possible to increase the proportion of high molecular weight components (for example, components having a molecular weight of 100,000 or more), the weight-average molecular weight, and the number-average molecular weight of the polymer and to further inhibit pattern top loss of a resist pattern.

The polymerization time is preferably 7 hours or more, more preferably 20 hours or more, and even more preferably 40 hours or more, and is preferably 120 hours or less, more preferably 90 hours or less, and even more preferably 60 hour or less. Adopting a polymerization time of 7 hours or more makes it possible to increase the proportion of high molecular weight components (for example, components having a molecular weight of 100,000 or more), the weight-average molecular weight, and the number-average molecular weight of the polymer and to further inhibit pattern top loss of a resist pattern. On the other hand, adopting a polymerization time of 120 hours or less makes it possible to efficiently produce the desired polymer.

In one example of a method of producing the polymer, a radical polymerization initiator such as azobisisobutyronitrile is preferably used as the polymerization initiator as previously described. Moreover, the content of the polymerization initiator relative to 100 parts by mass, in total, of the monomer (a) and the monomer (b) is preferably 0.07 parts by mass or less, more preferably 0.05 parts by mass or less, even more preferably 0.03 parts by mass or less, and particularly preferably 0.02 parts by mass or less. When the content of the polymerization initiator is 0.07 parts by mass or less relative to 100 parts by mass, in total, of the monomer (a) and the monomer (b) in this manner, the proportion of high molecular weight components (for example, components having a molecular weight of 100,000 or more) in the polymer and the weight-average molecular weight and number-average molecular weight of the polymer can be increased, and pattern top loss of a resist pattern can be further inhibited.

In one example of a method of producing the polymer, the use of a polymerization initiator is not essential. Polymerization of a monomer composition containing the monomer (a) and the monomer (b) can be initiated through adjustment of various conditions even without using a polymerization initiator.

In one example of a method of producing the polymer, cyclopentanone may be used as a solvent contained in the monomer composition as previously described, for example. The content of the solvent in the monomer composition is preferably 19 mass % or more, more preferably 23 mass % or more, and even more preferably 32 mass % or more, and is preferably 90 mass % or less, and more preferably 70 mass % or less. When the content of the solvent in the monomer composition is 19 mass % or more, the rate of polymerization can easily be controlled. On the other hand, when the content of the solvent in the monomer composition is 90 mass % or less, this enables highly efficient collection of a polymerized product.

In one example of a method of producing the polymer, the previously described purification of a polymerized product may be performed as necessary.

(Positive Resist Composition)

The presently disclosed positive resist composition contains the polymer set forth above and a solvent, and may optionally further contain known additives that can be included in positive resist compositions. As a result of the presently disclosed positive resist composition containing the polymer set forth above as a positive resist, a resist pattern in which pattern top loss is inhibited can be formed well by using a resist film that is obtained by applying the presently disclosed positive resist composition onto a substrate and then drying the presently disclosed positive resist composition.

<Solvent>

The solvent is not specifically limited so long as it is a solvent in which the polymer set forth above can dissolve and may, for example, be a known solvent such as described in JP5938536B1. Of such solvents, n-pentyl esters, n-hexyl esters, 2-methoxy-l-methylethyl acetate, and isoamyl acetate, which are esters of organic acids, and mixtures thereof are preferable as the solvent from a viewpoint of obtaining a positive resist composition of suitable viscosity and improving coatability of the positive resist composition, with 2-methoxy-1-methylethyl acetate, isoamyl acetate, and mixtures thereof being more preferable, and isoamyl acetate being even more preferable.

### EXAMPLES

The following provides a more specific description of the present disclosure based on examples. However, the present disclosure is not limited to the following examples. In the following description, “%” and “parts” used in expressing quantities are by mass, unless otherwise specified.

In the examples and comparative examples, the following methods were used to evaluate the weight-average molecular weight, number-average molecular weight, and molecular weight distribution of a polymer, the proportions of components having various molecular weights in a polymer, and the y value, Eth, remaining film fraction, remaining film fraction of a residual pattern (inhibition of pattern top loss), and resolution for a positive resist formed of a polymer.

### <Weight-average Molecular Weight, Number-average Molecular Weight, and Molecular Weight Distribution>

The weight-average molecular weight (Mw) and number-average molecular weight (Mn) of each type of polymer obtained in the examples and comparative examples were measured by gel permeation chromatography, and then the molecular weight distribution (Mw/Mn) of the polymer was calculated.

Specifically, the weight-average molecular weight (Mw) and number-average molecular weight (Mn) of the polymer were determined as standard polystyrene-equivalent values using a gel permeation chromatograph (HLC-8220 produced by Tosoh Corporation) and using tetrahydrofuran as an eluent solvent. The molecular weight distribution (Mw/Mn) was then calculated.

### <Proportions of Components Having Various Molecular Weights in Polymer>

A GPC chart of a polymer was obtained using a gel permeation chromatograph (HLC-8220 produced by Tosoh Corporation) and using tetrahydrofuran as an eluent solvent. The total area (A) of all peaks, the total area (B) of peaks for components having a molecular weight of less than 10,000, the total area (C) of peaks for components having a molecular weight of 100,000 or more, the total area (D) of peaks for components having a molecular weight of 120,000 or more, the total area (E) of peaks for components having a molecular weight of 140,000 or more, and the total area (F) of peaks for components having a molecular weight of 200,000 or more were determined from the obtained GPC chart. The proportions of components having various molecular weights were calculated using the following formulae.

Proportion of components having molecular weight of less than 10,000(%)=(B/A)×100

Proportion of components having molecular weight of 100,000 or more (%)=(C/A)×100

Proportion of components having molecular weight of 120,000 or more (%)=(D/A)×100

Proportion of components having molecular weight of 140,000 or more (%)=(E/A)×100

Proportion of components having molecular weight of 200,000 or more (%)=(F/A)×100

### <γ Value>

A spin coater (MS-A150 produced by Mikasa Co., Ltd.) was used to apply a positive resist composition produced in each example or comparative example onto a silicon wafer of 4 inches in diameter such as to have a thickness of 500 nm. The applied positive resist composition was heated for 3 minutes by a hot plate having a temperature of 180° C. to form a resist film on the silicon wafer. An electron beam lithography tool (ELS-S50 produced by Elionix Inc.)

was used to write a plurality of patterns (dimensions: 500 μm×500 μm) over the resist film with different electron beam irradiation doses, and development treatment was carried out for 1 minute at a temperature of 23° C. using a fluorinated solvent (produced by Chemours-Mitsui Fluoroproducts Co., Ltd.; Vertrel XF® (Vertrel XF is a registered trademark in Japan, other countries, or both); CF₃CFHCFHCF₂CF₃) as a resist developer. Note that the electron beam irradiation dose was varied in a range of 4 μC/cm² to 200 μC/cm² in increments of 4 μC/cm². Next, an optical film thickness measurement tool (Lambda Ace produced by SCREEN Semiconductor Solutions Co., Ltd.) was used to measure the thickness of the resist film in regions in which writing had been performed. A sensitivity curve was prepared that indicated a relationship between the common logarithm of the total electron beam irradiation dose and the remaining film fraction of the resist film after development (=thickness of resist film after development/thickness of resist film formed on silicon wafer). The y value was determined by using the formula described below with respect to the obtained sensitivity curve (horizontal axis: common logarithm of total electron beam irradiation dose; vertical axis: remaining film fraction of resist film (0≤remaining film fraction≤1.00)). In the following formula, E₀ is the logarithm of the total irradiation dose obtained when the sensitivity curve is fitted to a quadratic function in a range from a remaining film fraction of 0.20 to a remaining film fraction of 0.80, and then a remaining film fraction of 0 is substituted with respect to the obtained quadratic function (function of remaining film fraction and common logarithm of total irradiation dose). Also, E₁ is the logarithm of the total irradiation dose obtained when a straight line is prepared that joins points on the obtained quadratic function corresponding to remaining film fractions of 0 and 0.50 (linear approximation for gradient of sensitivity curve), and then a remaining film fraction of 1.00 is substituted with respect to the obtained straight line (function of remaining film fraction and common logarithm of total irradiation dose). The following formula expresses the gradient of the straight line between a remaining film fraction of 0 and a remaining film fraction of 1.00.

$$γ = {\vert {log}_{10} ( \frac{{E}_{1}}{{E}_{0}} ) \vert}^{- 1}$$

A larger γ value indicates that the sensitivity curve has a larger gradient and that a pattern having high clarity can be better formed.

### <Eth>

A positive resist composition produced in each example or comparative example was used to form a resist film on a silicon wafer in the same way as in the evaluation method of the “γ value”. The initial thickness T₀ of the obtained resist film was measured using an optical film thickness measurement tool (Lambda Ace produced by SCREEN Semiconductor Solutions Co., Ltd.). The total electron beam irradiation dose Eth (μC/cm²) corresponding to a remaining film fraction of 0 on the straight line (linear approximation for gradient of sensitivity curve) obtained in calculation of the γ value was determined. A smaller value for Eth indicates higher resist film sensitivity and higher resist pattern formation efficiency.

### <Remaining Film Fraction>

The electron beam irradiation doses that varied in a range of 4 μC/cm² to 200 μC/cm² in increments of 4 μC/cm² in preparation of the sensitivity curve (i.e., irradiation doses of 4, 8, 12, 16 . . . 196, and 200 μC/cm²) were each divided by Eth determined as described above.

In a case in which there was an electron beam irradiation dose for which the resultant value (electron beam irradiation dose/Eth) was 0.80, the remaining film fraction at that electron beam irradiation dose was taken to be a remaining film fraction (0.80 Eth).

In a case in which there was not an electron beam irradiation dose for which the resultant value (electron beam irradiation dose/Eth) was 0.80, the two values closest to 0.80 among these values were identified, and the electron beam irradiation doses for these two points were taken to be P (μC/cm²) and P+4 (μC/cm²), respectively. A remaining film fraction (0.80 Eth) was then determined by the following formula.

Remaining film fraction (0.80 Eth)=S−{(S−T)/(V−U)}×(0.80−U)

In this formula:

S represents the remaining film fraction at the electron beam irradiation dose P;

T represents the remaining film fraction at the electron beam irradiation dose P+4;

U represents P/Eth; and

V represents (P+4)/Eth.

A remaining film fraction (0.90 Eth) at an electron beam irradiation dose for which the resultant value (electron beam irradiation dose/Eth) was 0.90 was determined in the same manner.

Higher remaining film fractions at 0.80 Eth and 0.90 Eth calculated in this manner indicate that the resist film is more resistant to dissolving in a developer at irradiation doses lower than a total electron beam irradiation dose that enables a remaining film fraction of roughly 0. In other words, this indicates that the resist film has low solubility in the developer in a surrounding region of a pattern formation region of the resist film, which is a region having a comparatively low irradiation dose. Accordingly, high remaining film fractions calculated as described above indicate that there is a clear boundary between a region where the resist film is to be dissolved to form a pattern and a region where the resist film is to remain without dissolving, and thus indicate high pattern clarity. Moreover, when the remaining film fractions described above are high, this indicates that the resist is not easily influenced by irradiation noise in a non-irradiated region and that the resolution of an obtained resist pattern can be sufficiently increased.

### <Remaining Film Fraction of Residual Pattern>

A spin coater (MS-A150 produced by Mikasa Co., Ltd.) was used to apply a positive resist composition produced in each example or comparative example onto a silicon wafer of 4 inches in diameter such as to have a thickness of 50 nm. The applied positive resist composition was heated for 3 minutes by a hot plate having a temperature of 180° C. to form a positive resist film on the silicon wafer. An electron beam lithography tool (ELS-S50 produced by Elionix Inc.) was used to perform electron beam writing of a 1:1 line-and-space pattern having a line width of 25 nm with an optimal exposure dose (Eop) for each example or comparative example so as to obtain an electron beam-written wafer. Note that the optimal exposure dose was set as appropriate with a value approximately double Eth as a rough guide.

The electron beam-written wafer was subjected to development treatment through 1 minute of immersion in a fluorinated solvent (produced by Chemours-Mitsui Fluoroproducts Co., Ltd.; Vertrel XF; CF₃CFHCFHCF₂CF₃) as a resist developer at 23° C. Thereafter, 10 seconds of rinsing treatment was performed at a temperature of 23° C. using C₄F₉OCH₃ (Novec® 7100 (Novec is a registered trademark in Japan, other countries, or both) produced by 3M), which is a hydrofluoroether solvent, as a rinsing liquid so as to form a line-and-space pattern. A pattern section was then cleaved and was observed at ×100,000 magnification using a scanning electron microscope (JSM-7800F PRIME produced by JEOL Ltd.) in order to measure the maximum height (Tₘₐₓ) of the resist pattern after development and the initial thickness To of the resist film in an unexposed section. The “remaining film fraction (%) of a residual pattern” was determined by the following formula. A higher remaining film fraction for the residual pattern indicates less pattern top loss of the resist pattern.

Remaining film fraction of residual pattern (%)=(Tₘₐₓ/T₀)×100

### <Resolution>

A positive resist composition produced in each example or comparative example was used to form a resist film on a silicon wafer in the same way as in the evaluation method of “Remaining film fraction of residual pattern”. An electron beam lithography tool (ELS-S50 produced by Elionix Inc.) was used to perform electron beam writing of 1:1 line-and-space patterns having line widths of 18 nm, 20 nm, and 25 nm with an optimal exposure dose (Eop) for each example or comparative example so as to obtain an electron beam-written wafer. Note that the optimal exposure dose was set as appropriate with a value approximately double Eth as a rough guide.

The electron beam-written wafer was subjected to development treatment through 1 minute of immersion in a fluorinated solvent (produced by Chemours-Mitsui Fluoroproducts Co., Ltd.; Vertrel XF; CF₃CFHCFHCF₂CF₃) as a resist developer at 23° C. Thereafter, 10 seconds of rinsing treatment was performed at a temperature of 23° C. using C₄F₉OCH₃ (Novec 7100 produced by 3M), which is a hydrofluoroether solvent, as a rinsing liquid so as to form line-and-space patterns. The smallest line-and-space width for which a pattern was resolved was investigated through observation at ×100,000 magnification using a scanning electron microscope (JSM-7800F PRIME produced by JEOL Ltd.) and was evaluated by the following standard.

A: Smallest line-and-space width for which pattern is resolved is 18 nm or less

B: Smallest line-and-space width for which pattern is resolved is more than 18 nm and less than 25 nm

C: Smallest line-and-space width for which pattern is resolved is 25 nm or more

### Example 1

### <Production of Polymer (Crude)>

### [Polymerization of Monomer Composition]

A monomer composition containing 3.0 g of 2,2,3,3,3-pentafluoropropyl α-chloroacrylate (ACAPFP) as monomer (a), 3.4764 g of α-methylstyrene (AMS) as monomer (b), 0.0055 g of azobisisobutyronitrile as a polymerization initiator, and 1.6205 g of cyclopentanone as a solvent was loaded into a glass container. The glass container was tightly sealed and purged with nitrogen, and was then stirred for 6 hours in a 78° C. thermostatic tank under a nitrogen atmosphere. Thereafter, the glass container was returned to room temperature, the inside of the glass container was opened to the atmosphere, and then 10 g of tetrahydrofuran (THF) was added to the resultant solution. The solution to which the THF had been added was then dripped into 300 g of methanol to cause precipitation of a polymerized product. Thereafter, the solution containing the polymerized product that had precipitated was filtered using a Kiriyama funnel to obtain a white coagulated material (polymer; crude). The obtained polymer (crude) comprised 50 mol % of 2,2,3,3,3-pentafluoropropyl α-chloroacrylate units and 50 mol % of α-methylstyrene units.

### [Purification of Polymer (Crude)]

The obtained polymer (crude) was subsequently dissolved in 100 g of THF, and the resultant solution was dripped into a mixed solvent of 250 g of THF and 750 g of methanol to cause precipitation of a white coagulated material (polymer including α-methylstyrene units and 2,2,3,3,3-pentafluoropropyl α-chloroacrylate units). Thereafter, the solution containing the polymer that had precipitated was filtered using a Kiriyama funnel to obtain a white polymer. The weight-average molecular weight, number-average molecular weight, and molecular weight distribution of the obtained polymer, and the proportions of components having various molecular weights in the polymer were measured. The results are shown in Table 1.

### <Production of Positive Resist Composition>

The obtained polymer was dissolved in isoamyl acetate as a solvent to produce a positive resist composition having a polymer concentration of 11% and a positive resist composition having a polymer concentration of 2%. The positive resist composition having a polymer concentration of 11% was used to evaluate the y value, Eth, and remaining film fraction as previously described. The positive resist composition having a polymer concentration of 2% was used to evaluate the remaining film fraction of a residual pattern and the resolution as previously described. The results are shown in Table 1.

### Example 2

### <Production of Polymer (Crude)>

### [Polymerization of Monomer Composition]

A monomer composition containing 3.0 g of 2,2,3,3,3-pentafluoropropyl α-chloroacrylate (ACAPFP) as monomer (a), 3.2832 g of α-methylstyrene (AMS) as monomer (b), 0.00052 g of azobisisobutyronitrile as a polymerization initiator, and 1.5709 g of cyclopentanone as a solvent was loaded into a glass container. The glass container was tightly sealed and purged with nitrogen, and was then stirred for 2 hours in a 78° C. thermostatic tank under a nitrogen atmosphere. Thereafter, the glass container was returned to room temperature, the inside of the glass container was opened to the atmosphere, and then 10 g of THF was added to the resultant solution. The solution to which the THF had been added was then dripped into 300 g of methanol to cause precipitation of a polymerized product. Thereafter, the solution containing the polymerized product that had precipitated was filtered using a Kiriyama funnel to obtain a white coagulated material (polymer; crude). The obtained polymer (crude) comprised 50 mol % of α-methylstyrene units and 50 mol % of 2,2,3,3,3-pentafluoropropyl α-chloroacrylate units. The weight-average molecular weight, number-average molecular weight, and molecular weight distribution of the polymer (crude) collected by filtration without performing “Purification of polymer (crude)”, and the proportions of components having various molecular weights in the polymer were measured. The results are shown in Table 1.

### <Production of Positive Resist Composition>

Positive resist compositions were produced in the same way as in Example 1 with the exception that the polymer (crude) obtained as described above was used instead of using the polymer that had undergone purification. Evaluations were conducted in the same manner as in Example 1. The results are shown in Table 1.

### Example 3

Positive resist compositions were produced in the same way as in Example 2 with the exception that a polymer obtained through purification of the polymer (crude) as described below was used instead of using the polymer (crude) in Example 2. Evaluations were conducted in the same manner as in Example 1. The results are shown in Table 1.

### [Purification of Polymer (Crude)]

The obtained polymer (crude) was dissolved in 100 g of THF, and the resultant solution was dripped into a mixed solvent of 150 g of THF and 850 g of methanol to cause precipitation of a white coagulated material (polymer including α-methylstyrene units and 2,2,3,3,3-pentafluoropropyl α-chloroacrylate units). Thereafter, the solution containing the polymer that had precipitated was filtered using a Kiriyama funnel to obtain a white polymer.

### Example 4

A polymer and positive resist compositions were produced in the same way as in Example 3 with the exception that a mixed solvent of 160 g of THF and 840 g of methanol was used instead of the mixed solvent of 150 g of THF and 850 g of methanol in purification of the polymer (crude). Evaluations were conducted in the same manner as in Example 1. The results are shown in Table 1.

### Example 5

A polymer and positive resist compositions were produced in the same way as in Example 3 with the exception that a mixed solvent of 170 g of THF and 830 g of methanol was used instead of the mixed solvent of 150 g of THF and 850 g of methanol in purification of the polymer (crude). Evaluations were conducted in the same manner as in Example 1. The results are shown in Table 1.

### Example 6

A polymer and positive resist compositions were produced in the same way as in Example 3 with the exception that a mixed solvent of 180 g of THF and 820 g of methanol was used instead of the mixed solvent of 150 g of THF and 850 g of methanol in purification of the polymer (crude). Evaluations were conducted in the same manner as in Example 1. The results are shown in Table 1.

### Example 7

A polymer and positive resist compositions were produced in the same way as in Example 3 with the exception that a mixed solvent of 190 g of THF and 810 g of methanol was used instead of the mixed solvent of 150 g of THF and 850 g of methanol in purification of the polymer (crude). Evaluations were conducted in the same manner as in Example 1. The results are shown in Table 1.

### Example 8

A polymer and positive resist compositions were produced in the same way as in Example 3 with the exception that a mixed solvent of 200 g of THF and 800 g of methanol was used instead of the mixed solvent of 150 g of THF and 850 g of methanol in purification of the polymer (crude). Evaluations were conducted in the same manner as in Example 1. The results are shown in Table 1.

### Example 9

A polymer and positive resist compositions were produced in the same way as in Example 3 with the exception that a mixed solvent of 210 g of THF and 790 g of methanol was used instead of the mixed solvent of 150 g of THF and 850 g of methanol in purification of the polymer (crude). Evaluations were conducted in the same manner as in Example 1. The results are shown in Table 1.

### Example 10

A polymer and positive resist compositions were produced in the same way as in Example 3 with the exception that a mixed solvent of 220 g of THF and 780 g of methanol was used instead of the mixed solvent of 150 g of THF and 850 g of methanol in purification of the polymer (crude). Evaluations were conducted in the same manner as in Example 1. The results are shown in Table 1.

### Example 11

### <Production of Polymer (Crude)>

### [Polymerization Of Monomer Composition]

A monomer composition containing 3.0 g of 2,2,3,3,3-pentafluoropropyl α-chloroacrylate (ACAPFP) as monomer (a), 3.4680 g of α-methylstyrene (AMS) as monomer (b), 0.0021 g of azobisisobutyronitrile as a polymerization initiator, and 6.4659 g of cyclopentanone as a solvent was loaded into a glass container. The glass container was tightly sealed and purged with nitrogen, and was then stirred for 50 hours in a 53° C. thermostatic tank under a nitrogen atmosphere. Thereafter, the glass container was returned to room temperature, the inside of the glass container was opened to the atmosphere, and then 10 g of THF was added to the resultant solution. The solution to which the THF had been added was then dripped into 300 g of methanol to cause precipitation of a polymerized product. Thereafter, the solution containing the polymerized product that had precipitated was filtered using a Kiriyama funnel to obtain a white coagulated material (polymer; crude). The obtained polymer (crude) comprised 50 mol % of α-methylstyrene units and 50 mol % of 2,2,3,3,3-pentafluoropropyl α-chloroacrylate units. The weight-average molecular weight, number-average molecular weight, and molecular weight distribution of the polymer (crude) collected by filtration without performing “Purification of polymer (crude)”, and the proportions of components having various molecular weights in the polymer were measured. The results are shown in Table 2.

### <Production of Positive Resist Composition>

Positive resist compositions were produced in the same way as in Example 1 with the exception that the polymer (crude) obtained as described above was used instead of using the polymer that had undergone purification. Evaluations were conducted in the same manner as in Example 1. The results are shown in Table 2.

### Example 12

Positive resist compositions were produced in the same way as in Example 11 with the exception that a polymer obtained through purification of the polymer (crude) as described below was used instead of using the polymer (crude) in Example 11. Evaluations were conducted in the same manner as in Example 1. The results are shown in Table 2.

### [Purification of Polymer (Crude)]

The obtained polymer (crude) was dissolved in 100 g of THF, and the resultant solution was dripped into a mixed solvent of 150 g of THF and 850 g of methanol to cause precipitation of a white coagulated material (polymer including α-methylstyrene units and 2,2,3,3,3-pentafluoropropyl α-chloroacrylate units). Thereafter, the solution containing the polymer that had precipitated was filtered using a Kiriyama funnel to obtain a white polymer. The weight-average molecular weight, number-average molecular weight, and molecular weight distribution of the obtained polymer, and the proportions of components having various molecular weights in the polymer were measured. The results are shown in Table 2.

### Example 13

A polymer and positive resist compositions were produced in the same way as in Example 12 with the exception that a mixed solvent of 200 g of THF and 800 g of methanol was used instead of the mixed solvent of 150 g of THF and 850 g of methanol in purification of the polymer (crude). Evaluations were conducted in the same manner as in Example 1. The results are shown in Table 2.

### Example 14

A polymer and positive resist compositions were produced in the same way as in Example 12 with the exception that a mixed solvent of 210 g of THF and 790 g of methanol was used instead of the mixed solvent of 150 g of THF and 850 g of methanol in purification of the polymer (crude). Evaluations were conducted in the same manner as in Example 1. The results are shown in Table 2.

### Example 15

A polymer and positive resist compositions were produced in the same way as in Example 12 with the exception that a mixed solvent of 220 g of THF and 780 g of methanol was used instead of the mixed solvent of 150 g of THF and 850 g of methanol in purification of the polymer (crude). Evaluations were conducted in the same manner as in Example 1. The results are shown in Table 2.

### Example 16

A polymer and positive resist compositions were produced in the same way as in Example 12 with the exception that a mixed solvent of 230 g of THF and 770 g of methanol was used instead of the mixed solvent of 150 g of THF and 850 g of methanol in purification of the polymer (crude). Evaluations were conducted in the same manner as in Example 1. The results are shown in Table 2.

### Example 17

A polymer and positive resist compositions were produced in the same way as in Example 12 with the exception that a mixed solvent of 240 g of THF and 760 g of methanol was used instead of the mixed solvent of 150 g of THF and 850 g of methanol in purification of the polymer (crude). Evaluations were conducted in the same manner as in Example 1. The results are shown in Table 2.

### Example 18

A polymer and positive resist compositions were produced in the same way as in Example 12 with the exception that a mixed solvent of 250 g of THF and 750 g of methanol was used instead of the mixed solvent of 150 g of THF and 850 g of methanol in purification of the polymer (crude). Evaluations were conducted in the same manner as in Example 1. The results are shown in Table 2.

### Example 19

A polymer and positive resist compositions were produced in the same way as in Example 12 with the exception that a mixed solvent of 260 g of THF and 740 g of methanol was used instead of the mixed solvent of 150 g of THF and 850 g of methanol in purification of the polymer (crude). Evaluations were conducted in the same manner as in Example 1. The results are shown in Table 2.

### Example 20

A polymer and positive resist compositions were produced in the same way as in Example 12 with the exception that a mixed solvent of 270 g of THF and 730 g of methanol was used instead of the mixed solvent of 150 g of THF and 850 g of methanol in purification of the polymer (crude). Evaluations were conducted in the same manner as in Example 1. The results are shown in Table 2.

### Example 21

### <Production of Polymer (Crude)>

### [Polymerization of Monomer Composition]

A monomer composition containing 3.0 g of 2,2,3,3,3-pentafluoropropyl α-chloroacrylate (ACAPFP) as monomer (a), 3.4680 g of α-methylstyrene (AMS) as monomer (b), 0.0014 g of azobisisobutyronitrile as a polymerization initiator, and 6.4666 g of cyclopentanone as a solvent was loaded into a glass container. The glass container was tightly sealed and purged with nitrogen, and was then stirred for 50 hours in a 40° C. thermostatic tank under a nitrogen atmosphere. Thereafter, the glass container was returned to room temperature, the inside of the glass container was opened to the atmosphere, and then 10 g of THF was added to the resultant solution. The solution to which the THF had been added was then dripped into 300 g of methanol to cause precipitation of a polymerized product. Thereafter, the solution containing the polymerized product that had precipitated was filtered using a Kiriyama funnel to obtain a white coagulated material (polymer; crude). The obtained polymer (crude) comprised 50 mol % of α-methylstyrene units and 50 mol % of 2,2,3,3,3-pentafluoropropyl α-chloroacrylate units. The weight-average molecular weight, number-average molecular weight, and molecular weight distribution of the polymer (crude) collected by filtration without performing “Purification of polymer (crude)”, and the proportions of components having various molecular weights in the polymer were measured. The results are shown in Table 3.

### <Production of Positive Resist Composition>

Positive resist compositions were produced in the same way as in Example 1 with the exception that the polymer (crude) obtained as described above was used instead of using the polymer that had undergone purification.

Evaluations were conducted in the same manner as in Example 1. The results are shown in Table 3.

### Example 22

Positive resist compositions were produced in the same way as in Example 21 with the exception that a polymer obtained by purifying the polymer (crude) as described below was used instead of using the polymer (crude) in Example 21. Evaluations were conducted in the same manner as in Example 1. The results are shown in Table 3.

### [Purification of Polymer (Crude)]

The obtained polymer (crude) was dissolved in 100 g of THF, and the resultant solution was dripped into a mixed solvent of 150 g of THF and 850 g of methanol to cause precipitation of a white coagulated material (polymer including α-methylstyrene units and 2,2,3,3,3-pentafluoropropyl α-chloroacrylate units). Thereafter, the solution containing the polymer that had precipitated was filtered using a Kiriyama funnel to obtain a white polymer.

### Example 23

A polymer and positive resist compositions were produced in the same way as in Example 22 with the exception that a mixed solvent of 200 g of THF and 800 g of methanol was used instead of the mixed solvent of 150 g of THF and 850 g of methanol in purification of the polymer (crude). Evaluations were conducted in the same manner as in Example 1. The results are shown in Table 3.

### Example 24

A polymer and positive resist compositions were produced in the same way as in Example 22 with the exception that a mixed solvent of 250 g of THF and 750 g of methanol was used instead of the mixed solvent of 150 g of THF and 850 g of methanol in purification of the polymer (crude). Evaluations were conducted in the same manner as in Example 1. The results are shown in Table 3.

### Example 25

A polymer and positive resist compositions were produced in the same way as in Example 22 with the exception that a mixed solvent of 260 g of THF and 740 g of methanol was used instead of the mixed solvent of 150 g of THF and 850 g of methanol in purification of the polymer (crude). Evaluations were conducted in the same manner as in Example 1. The results are shown in Table 3.

### Example 26

A polymer and positive resist compositions were produced in the same way as in Example 22 with the exception that a mixed solvent of 270 g of THF and 730 g of methanol was used instead of the mixed solvent of 150 g of THF and 850 g of methanol in purification of the polymer (crude). Evaluations were conducted in the same manner as in Example 1. The results are shown in Table 3.

### Example 27

A polymer and positive resist compositions were produced in the same way as in Example 22 with the exception that a mixed solvent of 280 g of THF and 720 g of methanol was used instead of the mixed solvent of 150 g of THF and 850 g of methanol in purification of the polymer (crude). Evaluations were conducted in the same manner as in Example 1. The results are shown in Table 3.

### Example 28

### <Production of Polymer (Crude)>

### [Polymerization of Monomer Composition]

A monomer composition containing 3.0 g of 2,2,3,3,3-pentafluoropropyl α-chloroacrylate (ACAPFP) as monomer (a), 3.4680 g of α-methylstyrene (AMS) as monomer (b), 0.00069 g of azobisisobutyronitrile as a polymerization initiator, and 5.7796 g of cyclopentanone as a solvent was loaded into a glass container. The glass container was tightly sealed and purged with nitrogen, and was then stirred for 48 hours in a 35° C. thermostatic tank under a nitrogen atmosphere. Thereafter, the glass container was returned to room temperature, the inside of the glass container was opened to the atmosphere, and then 10 g of THF was added to the resultant solution. The solution to which the THF had been added was then dripped into 300 g of methanol to cause precipitation of a polymerized product. Thereafter, the solution containing the polymerized product that had precipitated was filtered using a Kiriyama funnel to obtain a white coagulated material (polymer; crude). The obtained polymer (crude) comprised 50 mol % of α-methylstyrene units and 50 mol % of 2,2,3,3,3-pentafluoropropyl α-chloroacrylate units. The weight-average molecular weight, number-average molecular weight, and molecular weight distribution of the polymer (crude) collected by filtration without performing “Purification of polymer (crude)”, and the proportions of components having various molecular weights in the polymer were measured. The results are shown in Table 3.

### <Production of Positive Resist Composition>

Positive resist compositions were produced in the same way as in Example 1 with the exception that the polymer (crude) obtained as described above was used instead of using the polymer that had undergone purification.

Evaluations were conducted in the same manner as in Example 1. The results are shown in Table 3.

### Example 29

A polymer (crude) and positive resist compositions were produced in the same way as in Example 28 with the exception that the amount of cyclopentanone used as a solvent was changed from 5.7796 g to 2.0836 g in production of the polymer (crude). Evaluations were conducted in the same manner as in Example 1. The results are shown in Table 3.

### Comparative Example 1

The weight-average molecular weight, number-average molecular weight, and molecular weight distribution of a polymer (crude) collected by filtration without performing purification of the polymer (crude) in Example 1, and the proportions of components having various molecular weights in the polymer were measured. The results are shown in Table 4.

Positive resist compositions were produced in the same way as in Example 1 with the exception that the polymer (crude) was used instead of using a polymer obtained by purifying the polymer (crude). Evaluations were conducted in the same manner as in Example 1. The results are shown in Table 4.

### Comparative Example 2

A polymer and positive resist compositions were produced in the same way as in Example 1 with the exception that a mixed solvent of 50 g of THF and 950 g of methanol was used instead of the mixed solvent of 250 g of THF and 750 g of methanol in purification of the polymer (crude). Evaluations were conducted in the same manner as in Example 1. The results are shown in Table 4.

### Comparative Example 3

A polymer and positive resist compositions were produced in the same way as in Example 1 with the exception that a mixed solvent of 100 g of THF and 900 g of methanol was used instead of the mixed solvent of 250 g of THF and 750 g of methanol in purification of the polymer (crude). Evaluations were conducted in the same manner as in Example 1. The results are shown in Table 4.

### Comparative Example 4

A polymer and positive resist compositions were produced in the same way as in Example 1 with the exception that a mixed solvent of 150 g of THF and 850 g of methanol was used instead of the mixed solvent of 250 g of THF and 750 g of methanol in purification of the polymer (crude). Evaluations were conducted in the same manner as in Example 1. The results are shown in Table 4.

### Comparative Example 5

A polymer and positive resist compositions were produced in the same way as in Example 1 with the exception that a mixed solvent of 200 g of THF and 800 g of methanol was used instead of the mixed solvent of 250 g of THF and 750 g of methanol in purification of the polymer (crude). Evaluations were conducted in the same manner as in Example 1. The results are shown in Table 4.

TABLE 1

| | | Example 1 | Example 2 | Example 3 | Example 4 | Example 5 | Example 6 |
|---|---|---|---|---|---|---|---|
| Polymer | Proportion of components having molecular | 0.559 | 1.723 | 0.472 | 0.342 | 0.320 | 0.272 |
| | weight of less than 10,000 [%] | | | | | | |
| | Proportion of components having molecular | 34.901 | 15.783 | 16.287 | 16.755 | 17.317 | 17.782 |
| | weight of 100,000 or more [%] | | | | | | |
| | Proportion of components having molecular | 26.691 | 11.866 | 12.331 | 12.677 | 13.083 | 13.453 |
| | weight of 120,000 or more [%] | | | | | | |
| | Proportion of components having molecular | 13.513 | 6.245 | 6.649 | 6.819 | 7.008 | 7.235 |
| | weight of 140,000 or more [%] | | | | | | |
| | Proportion of components having molecular | 3.853 | 2.121 | 2.406 | 2.451 | 2.493 | 2.602 |
| | weight of 200,000 or more [%] | | | | | | |
| | Weight-average molecular weight (Mw) [—] | 88337 | 68503 | 71963 | 72940 | 74377 | 75928 |
| | Number-average molecular weight (Mn) [—] | 57250 | 38615 | 46608 | 47704 | 49159 | 50993 |
| | Molecular weight distribution (Mw/Mn) [—] | 1.543 | 1.774 | 1.544 | 1.529 | 1.513 | 1.489 |
| Evaluation | Eth [μC/cm²] | 84.958 | 75.064 | 76.234 | 76.432 | 76.567 | 76.843 |
| | γ value [—] | 29.435 | 27.982 | 28.874 | 29.123 | 29.502 | 29.564 |
| | Remaining film fraction with irradiation dose | 0.865 | 0.852 | 0.880 | 0.882 | 0.884 | 0.888 |
| | of 0.80Eth [—] | | | | | | |
| | Remaining film fraction with irradiation dose | 0.774 | 0.769 | 0.783 | 0.791 | 0.795 | 0.801 |
| | of 0.90Eth [—] | | | | | | |
| | Remaining film fraction of residual pattern [%] | 86.9 | 87.0 | 88.6 | 88.9 | 89.5 | 90.0 |
| | Resolution | C | C | B | B | B | B |

| | | Example 7 | Example 8 | Example 9 | Example 10 |
|---|---|---|---|---|---|
| Polymer | Proportion of components having molecular | 0.210 | 0.210 | 0.220 | 0.246 |
| | weight of less than 10,000 [%] | | | | |
| | Proportion of components having molecular | 18.911 | 18.412 | 21.696 | 21.562 |
| | weight of 100,000 or more [%] | | | | |
| | Proportion of components having molecular | 14.309 | 13.942 | 16.459 | 16.290 |
| | weight of 120,000 or more [%] | | | | |
| | Proportion of components having molecular | 7.690 | 7.527 | 8.902 | 8.750 |
| | weight of 140,000 or more [%] | | | | |
| | Proportion of components having molecular | 2.755 | 2.735 | 3.228 | 3.152 |
| | weight of 200,000 or more [%] | | | | |
| | Weight-average molecular weight (Mw) [—] | 78763 | 82912 | 85192 | 86115 |
| | Number-average molecular weight (Mn) [—] | 53690 | 57063 | 59952 | 61205 |
| | Molecular weight distribution (Mw/Mn) [—] | 1.467 | 1.453 | 1.421 | 1.407 |
| Evaluation | Eth [μC/cm²] | 76.999 | 77.434 | 77.536 | 77.553 |
| | γ value [—] | 29.795 | 29.834 | 29.995 | 30.232 |
| | Remaining film fraction with irradiation dose | 0.891 | 0.899 | 0.901 | 0.900 |
| | of 0.80Eth [—] | | | | |
| | Remaining film fraction with irradiation dose | 0.810 | 0.812 | 0.816 | 0.814 |
| | of 0.90Eth [—] | | | | |
| | Remaining film fraction of residual pattern [%] | 90.5 | 90.8 | 91.2 | 91.3 |
| | Resolution | A | A | A | A |

TABLE 2

| | | Example 11 | Example 12 | Example 13 | Example 14 | Example 15 | Example 16 |
|---|---|---|---|---|---|---|---|
| Polymer | Proportion of components having molecular | 0.711 | 0.181 | 0.091 | 0.110 | 0.094 | 0.098 |
| | weight of less than 10,000 [%] | | | | | | |
| | Proportion of components having molecular | 29.712 | 29.892 | 33.348 | 35.188 | 36.403 | 39.032 |
| | weight of 100,000 or more [%] | | | | | | |
| | Proportion of components having molecular | 24.218 | 26.996 | 28.495 | 29.441 | 31.567 | 39.249 |
| | weight of 120,000 or more [%] | | | | | | |
| | Proportion of components having molecular | 14.892 | 16.595 | 17.531 | 18.082 | 19.361 | 24.401 |
| | weight of 140,000 or more [%] | | | | | | |
| | Proportion of components having molecular | 6.289 | 7.025 | 7.434 | 7.664 | 8.184 | 10.398 |
| | weight of 200,000 or more [%] | | | | | | |
| | Weight-average molecular weight (Mw) [—] | 96042 | 98310 | 106315 | 109672 | 111636 | 116482 |
| | Number-average molecular weight (Mn) [—] | 51943 | 59546 | 70175 | 73903 | 76620 | 81172 |
| | Molecular weight distribution (Mw/Mn) [—] | 1.849 | 1.651 | 1.515 | 1.484 | 1.457 | 1.435 |
| Evaluation | Eth [μC/cm²] | 78.775 | 79.111 | 79.787 | 79.998 | 80.123 | 80.222 |
| | γ value [—] | 36.432 | 37.897 | 38.434 | 38.566 | 38.845 | 38.899 |
| | Remaining film fraction with irradiation dose | 0.890 | 0.919 | 0.926 | 0.925 | 0.924 | 0.922 |
| | of 0.80Eth [—] | | | | | | |
| | Remaining film fraction with irradiation dose | 0.812 | 0.856 | 0.867 | 0.856 | 0.855 | 0.853 |
| | of 0.90Eth [—] | | | | | | |
| | Remaining film fraction of residual pattern [%] | 89.3 | 91.2 | 91.6 | 91.9 | 92.4 | 92.8 |
| | Resolution | B | B | A | A | A | A |

| | | Example 17 | Example 18 | Example 19 | Example 20 |
|---|---|---|---|---|---|
| Polymer | Proportion of components having molecular | 0.133 | 0.063 | 0.165 | 0.549 |
| | weight of less than 10,000 [%] | | | | |
| | Proportion of components having molecular | 47.953 | 57.533 | 59.479 | 46.010 |
| | weight of 100,000 or more [%] | | | | |
| | Proportion of components having molecular | 48.187 | 50.781 | 40.776 | 34.358 |
| | weight of 120,000 or more [%] | | | | |
| | Proportion of components having molecular | 30.886 | 33.984 | 30.669 | 20.965 |
| | weight of 140,000 or more [%] | | | | |
| | Proportion of components having molecular | 13.404 | 15.461 | 17.468 | 8.671 |
| | weight of 200,000 or more [%] | | | | |
| | Weight-average molecular weight (Mw) [—] | 130365 | 144317 | 153901 | 143118 |
| | Number-average molecular weight (Mn) [—] | 92392 | 103602 | 106139 | 67861 |
| | Molecular weight distribution (Mw/Mn) [—] | 1.411 | 1.393 | 1.450 | 2.109 |
| Evaluation | Eth [μC/cm²] | 80.458 | 80.543 | 80.323 | 79.567 |
| | γ value [—] | 39.173 | 39.678 | 39.875 | 36.543 |
| | Remaining film fraction with irradiation dose | 0.920 | 0.924 | 0.918 | 0.913 |
| | of 0.80Eth [—] | | | | |
| | Remaining film fraction with irradiation dose | 0.852 | 0.856 | 0.848 | 0.844 |
| | of 0.90Eth [—] | | | | |
| | Remaining film fraction of residual pattern [%] | 93.7 | 94.3 | 94.2 | 93.1 |
| | Resolution | A | A | A | B |

TABLE 3

| | | Example 21 | Example 22 | Example 23 | Example 24 | Example 25 |
|---|---|---|---|---|---|---|
| Polymer | Proportion of components having molecular | 1.386 | 0.078 | 0.124 | 0.031 | 0.040 |
| | weight of less than 10,000 [%] | | | | | |
| | Proportion of components having molecular | 39.173 | 41.186 | 43.693 | 62.554 | 70.097 |
| | weight of 100,000 or more [%] | | | | | |
| | Proportion of components having molecular | 33.376 | 34.890 | 36.956 | 53.973 | 62.009 |
| | weight of 120,000 or more [%] | | | | | |
| | Proportion of components having molecular | 22.807 | 23.636 | 24.977 | 37.301 | 44.603 |
| | weight of 140,000 or more [%] | | | | | |
| | Proportion of components having molecular | 11.223 | 11.586 | 12.227 | 18.436 | 22.777 |
| | weight of 200,000 or more [%] | | | | | |
| | Weight-average molecular weight (Mw) [—] | 126213 | 124542 | 129904 | 165470 | 180605 |
| | Number-average molecular weight (Mn) [—] | 64362 | 72704 | 81701 | 116038 | 128728 |
| | Molecular weight distribution (Mw/Mn) [—] | 1.961 | 1.713 | 1.590 | 1.426 | 1.403 |
| Evaluation | Eth [μC/cm²] | 78.890 | 79.968 | 80.122 | 80.432 | 80.528 |
| | γ value [—] | 37.654 | 38.829 | 39.543 | 39.932 | 39.984 |
| | Remaining film fraction with irradiation dose | 0.888 | 0.924 | 0.920 | 0.927 | 0.922 |
| | of 0.80Eth [—] | | | | | |
| | Remaining film fraction with irradiation dose | 0.809 | 0.855 | 0.850 | 0.860 | 0.856 |
| | of 0.90Eth [—] | | | | | |
| | Remaining film fraction of residual pattern [%] | 92.8 | 95.2 | 95.5 | 96.1 | 96.8 |
| | Resolution | B | B | A | A | A |

| | | Example 26 | Example 27 | Example 28 | Example 29 |
|---|---|---|---|---|---|
| Polymer | Proportion of components having molecular | 0.228 | 1.320 | 0.011 | 0.293 |
| | weight of less than 10,000 [%] | | | | |
| | Proportion of components having molecular | 76.654 | 60.574 | 50.543 | 45.879 |
| | weight of 100,000 or more [%] | | | | |
| | Proportion of components having molecular | 71.875 | 56.877 | 44.372 | 39.974 |
| | weight of 120,000 or more [%] | | | | |
| | Proportion of components having molecular | 59.315 | 48.549 | 32.401 | 28.763 |
| | weight of 140,000 or more [%] | | | | |
| | Proportion of components having molecular | 36.419 | 33.721 | 17.705 | 15.398 |
| | weight of 200,000 or more [%] | | | | |
| | Weight-average molecular weight (Mw) [—] | 229306 | 242930 | 154285 | 142545 |
| | Number-average molecular weight (Mn) [—] | 157599 | 131527 | 77254 | 70174 |
| | Molecular weight distribution (Mw/Mn) [—] | 1.455 | 1.847 | 1.997 | 2.031 |
| Evaluation | Eth [μC/cm²] | 80.432 | 79.968 | 80.565 | 80.765 |
| | γ value [—] | 38.954 | 37.985 | 37.654 | 37.586 |
| | Remaining film fraction with irradiation dose | 0.914 | 0.900 | 0.923 | 0.920 |
| | of 0.80Eth [—] | | | | |
| | Remaining film fraction with irradiation dose | 0.849 | 0.823 | 0.856 | 0.853 |
| | of 0.90Eth [—] | | | | |
| | Remaining film fraction of residual pattern [%] | 96.3 | 95.8 | 96.3 | 96.1 |
| | Resolution | A | B | A | A |

TABLE 4

| | | Comparative | Comparative | Comparative | Comparative | Comparative |
|---|---|---|---|---|---|---|
| | | Example 1 | Example 2 | Example 3 | Example 4 | Example 5 |
| Polymer | Proportion of components having molecular | 3.193 | 1.662 | 0.958 | 0.512 | 0.239 |
| | weight of less than 10,000 [%] | | | | | |
| | Proportion of components having molecular | 6.184 | 6.623 | 6.653 | 6.938 | 9.154 |
| | weight of 100,000 or more [%] | | | | | |
| | Proportion of components having molecular | 4.150 | 4.480 | 4.493 | 4.686 | 6.196 |
| | weight of 120,000 or more [%] | | | | | |
| | Proportion of components having molecular | 1.722 | 1.895 | 1.893 | 1.980 | 2.633 |
| | weight of 140,000 or more [%] | | | | | |
| | Proportion of components having molecular | 0.418 | 0.477 | 0.471 | 0.497 | 0.668 |
| | weight of 200,000 or more [%] | | | | | |
| | Weight-average molecular weight (Mw) [—] | 43834 | 47048 | 47527 | 49556 | 57004 |
| | Number-average molecular weight (Mn) [—] | 25718 | 31640 | 32913 | 35806 | 43349 |
| | Molecular weight distribution (Mw/Mn) [—] | 1.704 | 1.487 | 1.444 | 1.384 | 1.315 |
| Evaluation | Eth [μC/cm²] | 83.341 | 83.983 | 84.123 | 85.003 | 84.567 |
| | γ value [—] | 27.213 | 29.011 | 29.321 | 30.316 | 31.232 |
| | Remaining film fraction with irradiation dose | 0.823 | 0.845 | 0.858 | 0.876 | 0.884 |
| | of 0.80Eth [—] | | | | | |
| | Remaining film fraction with irradiation dose | 0.734 | 0.751 | 0.766 | 0.780 | 0.791 |
| | of 0.90Eth [—] | | | | | |
| | Remaining film fraction of residual pattern [%] | 83.4 | 84.3 | 85.4 | 85.9 | 86.3 |
| | Resolution | C | C | C | B | B |

It can be seen from Tables 1 to 3 that in Examples 1 to 29 in which the used polymer included the specific monomer unit (A) and the specific monomer unit (B) and had a proportion of components having a molecular weight of 100,000 or more that was not less than a specific value, it was possible to form a resist pattern in which pattern top loss was sufficiently inhibited. In contrast, it can be seen from Table 4 that in Comparative Examples 1 to 5 in which the used polymer had a proportion of components having a molecular weight of 100,000 or more that was less than the specific value, it was not possible to inhibit pattern top loss of a resist pattern compared to in Examples 1 to 29.

### INDUSTRIAL APPLICABILITY

According to the present disclosure, it is possible to provide a polymer that can be used well as a positive resist capable of forming a resist pattern in which pattern top loss is inhibited.

Moreover, according to the present disclosure, it is possible to provide a positive resist composition that is capable of forming a resist pattern in which pattern top loss is inhibited.

1. A polymer comprising:
a monomer unit (A) represented by general formula (I), shown below, 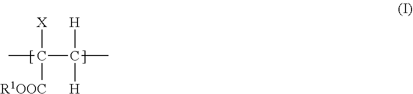
where, in general formula (I), X is a fluorine atom, a chlorine atom, a bromine atom, an iodine atom, or an astatine atom, and R¹ is an organic group including not fewer than 3 and not more than 7 fluorine atoms; and
a monomer unit (B) represented by general formula (II), shown below, 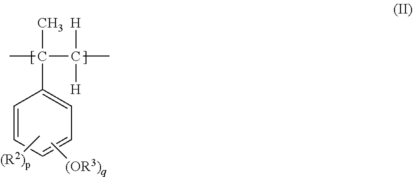
where, in general formula (II), R² is a hydrogen atom, a fluorine atom, an unsubstituted alkyl group, or a fluorine atom-substituted alkyl group, R³ is a hydrogen atom, an unsubstituted alkyl group, or a fluorine atom-substituted alkyl group, p and q are integers of not less than 0 and not more than 5, and p+q=5, wherein a proportion of components having a molecular weight of 100,000 or more is 10% or more.

2. The polymer according to claim 1, wherein X in general formula (I) is a chlorine atom.

3. The polymer according to claim 1, wherein a proportion of components having a molecular weight of less than 10,000 is 0.5% or less.

4. The polymer according to claim 1, having a weight-average molecular weight (Mw) of more than 60,000.

5. The polymer according to claim 1, having a molecular weight distribution (Mw/Mn) of less than 2.3.

6. A positive resist composition comprising: the polymer according to claim 1; and a solvent.
